(19) United States
(12) Patent Application Publication
(10) Pub. No.: US 2023/0197812 A1
(43) Pub. Date: Jun. 22, 2023

(54) HYBRID CHANNEL REGION FOR GATE ALL AROUND (GAA) TRANSISTOR STRUCTURES

(71) Applicant: Intel Corporation, Santa Clara, CA (US)

(72) Inventors: Anand Murthy, Portland, OR (US); Prashant Majhi, San Jose, CA (US); Glenn Glass, Portland, OR (US)

(73) Assignee: Intel Corporation, Santa Clara, CA (US)

(21) Appl. No.: 17/553,397

(22) Filed: Dec. 16, 2021

(51) Int. Cl. H01L 29/423; H01L 27/092; H01L 29/786; H01L 29/06; H01L 29/04; H01L 21/8238

(52) U.S. Cl. CPC H01L 29/42392; H01L 27/092; H01L 29/78696; H01L 29/0665; H01L 29/045; H01L 21/823807

(57) ABSTRACT

An integrated circuit structure includes a substrate, a first device above a first section of the substrate, and a second device above a second section of the substrate. The first device includes a first source region and a first drain region, and a first body extending laterally between the first source and first drain regions. In an example, the first body includes silicon with crystalline orientation described by Miller index of (100). The second device includes a second source region and a second drain region, and a second body extending laterally between the second source and second drain regions. In an example, the second body includes silicon with crystalline orientation described by Miller index of (110).

### BACKGROUND

Semiconductor devices are electronic components that exploit the electronic properties of semiconductor materials, such as silicon (Si), germanium (Ge), gallium arsenide (GaAs), and indium phosphide (InP). A field-effect transistor (FET) is a semiconductor device that includes three terminals: a gate, a source, and a drain. A FET uses an electric field applied by the gate to control the electrical conductivity of a channel through which charge carriers (e.g., electrons or holes) flow between the source and drain. In instances where the charge carriers are electrons, the FET is referred to as an n-channel device; and in instances where the charge carriers are holes, the FET is referred to as a p-channel device. Some FETs have a fourth terminal called the body or substrate, which can be used to bias the transistor. In addition, metal-oxide-semiconductor FETs (MOSFETs) include a gate dielectric between the gate and the channel. MOSFETs may also be known as metal-insulator-semiconductor FETs (MISFETSs) or insulated-gate FETs (IGFETs). Complementary MOS (CMOS) structures use a combination of p-channel MOSFET (PMOS) and n-channel MOSFET (NMOS) devices to implement logic gates and other digital circuits.

A FinFET is a MOSFET transistor built around a thin strip of semiconductor material (generally referred to as a fin). The conductive channel of the FinFET device resides on the outer portions of the fin adjacent to the gate dielectric. Specifically, current runs along/within both sidewalls of the fin (sides perpendicular to the substrate surface) as well as along the top of the fin (side parallel to the substrate surface). Because the conductive channel of such configurations includes three different planer regions of the fin (e.g., top and two sides), such a FinFET design is sometimes referred to as a tri-gate transistor. A nanowire or nanoribbon transistor (sometimes referred to as a gate-all-around (GAA)) is configured similarly to a fin-based transistor, but instead of a finned channel region, one or more nanowires or nanoribbons extend between the source and the drain regions. In nanoribbon transistors, the gate material wraps around each nanoribbon (hence, gate-all-around).

### BRIEF DESCRIPTION OF THE DRAWINGS

FIGS. 1A, 1B, and 1C illustrate various perspective and cross-sectional views of an example GAA semiconductor structure, where the GAA semiconductor structure comprises (i) one or more P-channel metal-oxide-semiconductor (PMOS) devices with channel region(s) comprising semiconductor material with crystalline orientation described by a Miller index of (110) and (ii) one or more N-channel metal-oxide-semiconductor (NMOS) devices with channel region(s) comprising semiconductor material with crystalline orientation described by a Miller index of (100), in accordance with an embodiment of the present disclosure.

FIG. 2 illustrates a flowchart depicting a method of forming a GAA semiconductor structure (such as the GAA semiconductor structure of FIGS. 1A-1C), where the GAA semiconductor structure comprises (i) one or more P-channel metal-oxide-semiconductor (PMOS) devices with channel region(s) comprising semiconductor material with crystalline orientation described by a Miller index of (110) and (ii) one or more N-channel metal-oxide-semiconductor (NMOS) devices with channel region(s) comprising semiconductor material with crystalline orientation described by a Miller index of (100), in accordance with an embodiment of the present disclosure.

FIGS. 3A-3H collectively illustrate cross-sectional views of an example GAA semiconductor structure (e.g., the GAA semiconductor structure of FIGS. 1A-1C and 2) in various stages of processing, in accordance with an embodiment of the present disclosure.

FIGS. 4A and 4B illustrate perspective and cross-sectional views, respectively, of another example GAA semiconductor structure, where the GAA semiconductor structure comprises (i) two PMOS devices each with channel regions comprising semiconductor material with crystalline orientation described by a Miller index of (110) and (ii) one NMOS device with a channel region comprising semiconductor material with crystalline orientation described by a Miller index of (100), in accordance with an embodiment of the present disclosure.

FIG. 5 illustrates a computing system implemented with integrated circuit structures and/or transistor devices formed using the techniques disclosed herein, in accordance with an embodiment of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles (e.g., curved or tapered sidewalls and round corners), and some features may have surface topography or otherwise be non-smooth, given real-world limitations of fabrication processes. Further still, some of the features in the drawings may include a patterned and/or shaded fill, which is merely provided to assist in visually identifying the different features. In short, the figures are provided merely to show example structures.

### DETAILED DESCRIPTION

Integrated circuit structures including a first device having a first channel body with crystalline orientation described by Miller index of (100) and a second device having a second channel body with crystalline orientation described by Miller index of (110) are provided herein. In one example embodiment, an integrated circuit structure comprises a substrate, a first device above a first section of the substrate, and a second device above a second section of the substrate. The first device comprises a first source region and a first drain region, and a first body extending laterally between the first source and first drain regions. In an example, the first body comprises silicon with crystalline orientation described by Miller index of (100). The second device comprises a second source region and a second drain region, and a second body extending laterally between the second source and second drain regions. In an example, the second body comprises silicon with crystalline orientation described by Miller index of (110).

In another example embodiment, an integrated circuit structure comprises a first source region and a first drain region, and a first body extending laterally between the first source and first drain regions. The first body comprises first semiconductor material. The integrated circuit structure further comprises a second source region and a second drain region, and a second body extending laterally between the second source and second drain regions. The second body comprises second semiconductor material. In an example, a first crystalline orientation of the first semiconductor material is different from a second crystalline orientation of the second semiconductor material. For example, the first crystalline orientation is described by a Miller index of one of (110), (100), and (111), and the second crystalline orientation is described by a Miller index of another of (110), (100), and (111).

A method of forming an integrated circuit structure comprises forming a stack of alternating layers of sacrificial material and channel material above a substrate. In an example, each layer of channel material in the stack comprises (i) a first section having a first semiconductor material with a first crystalline orientation, and (ii) a second section having a second semiconductor material with a second crystalline orientation. The method further comprises selectively etching the stack to define at least a first fin and a second fin. In an example, the first fin has alternating layers of the first semiconductor material with the first crystalline orientation and the sacrificial material, and the second fin has alternating layers of the second semiconductor material with the second crystalline orientation and the sacrificial material. The method further comprises forming (i) a first source region and a first drain region, such that the first fin is laterally between the first source region and the first drain region, and (ii) a second source region and a second drain region, such that the second fin is laterally between the second source region and the second drain region. The method further comprises removing the sacrificial material from the first and second fins, such that (i) the layers of the first semiconductor material with the first crystalline orientation of the first fin form a first plurality of bodies laterally between the first source region and the first drain region, and (ii) the layers of the second semiconductor material with the second crystalline orientation of the second fin form a second plurality of bodies laterally between the second source region and the second drain region. In an example, the first source region, the first drain region, and the first plurality of bodies laterally between the first source region and the first drain region form a p-channel metal-oxide-semiconductor (PMOS) device, and the first crystalline orientation is described by a Miller index of (110). In an example, the second source region, the second drain region, and the second plurality of bodies laterally between the second source region and the second drain region form a n-channel metal-oxide-semiconductor (NMOS) device, and the second crystalline orientation is described by a Miller index of (100).

Methodologies and structures of the present disclosure can provide an improved Complementary metal-oxide-semiconductor (CMOS) circuit, where a PMOS device of the CMOS circuit comprises channel body having semiconductor material with crystalline orientation of (110), and where an NMOS device of the CMOS circuit comprises channel body having semiconductor material with crystalline orientation of (100), resulting in better performance matching between the PMOS and NMOS devices.

### GENERAL OVERVIEW

Field effect transistors (FETs) have been scaled to smaller and smaller sizes to achieve faster circuit operation. Such scaling has resulted in the development of transistors such as gate-all-around (GAA) transistors in which the gate fully wraps around a channel body, and forksheet transistors in which the gate at least partially wraps around a channel body. Examples of GAA transistors include nanoribbon or nanowire transistors. For example, the GAA channel region can have nanoribbons extending between the source and drain regions, such as a vertical stack of nanoribbons that extend horizontally between the source and drain regions. A complementary metal-oxide-semiconductor (CMOS) circuit includes PMOS GAA transistors and NMOS GAA transistors. Generally, GAA based CMOS circuits suffer from mismatch in performance characteristics between NMOS and PMOS transistors. For example, GAA PMOS and NMOS devices may have channel bodies having crystalline orientation described by a Miller index of (100), which is referred to herein as (100) channel body. However, in general, hole mobility in the (100) channel bodies of the PMOS transistors are less, e.g., compared to electron mobility in the (100) channel bodies of the NMOS transistors. This results in relatively strong NMOS performance and relatively poor PMOS performance, which in turn results in the above discussed mismatch in performance characteristics between NMOS and PMOS transistors. In an example, to address such mismatch in performance characteristics, channel bodies of both PMOS and NMOS may comprise semiconductor material with crystalline orientation described by a Miller index of (110). However, although (110) channel bodies in PMOS devices improve PMOS performance characteristics, the (110) channel bodies in NMOS devices result in relatively poor NMOS performance characteristics, which impacts the overall performance of the CMOS circuits. Another approach to address such mismatch in performance characteristics may be to induce strain for channel bodies of PMOS devices, however there are different process challenges with inducing such strain.

Thus, and in accordance with various embodiments of the present disclosure, techniques are disclosed for forming (i) PMOS devices with channel bodies comprising semiconductor material having crystalline orientation described by a Miller index of (110), and (ii) NMOS devices with channel bodies comprising semiconductor material having crystalline orientation described by a Miller index of (100). Use of (110) channel bodies in the PMOS devices increase carrier (e.g., hole) mobility in the channel bodies of the PMOS devices, which in turn improves the performance of the PMOS devices. On the other hand, use of (100) channel bodies in the NMOS devices preserves (e.g., does not reduce) the carrier (e.g., electron) mobility in the channel bodies of the NMOS devices. Accordingly, due to hybrid usages of (110) and (100) for the channel bodies of the PMOS and NMOS devices, respectively, now performance between the PMOS devices and the NMOS devices are relatively better matched, compared to a scenario where both PMOS and NMOS devices have (100) channel bodies, or where both PMOS and NMOS devices have (110) channel bodies. This improves overall performance of the CMOS circuits comprising the various PMOS and NMOS devices.

Thus, in one embodiment, a GAA structure comprises hybrid channel bodies, such as (110) channel bodies for PMOS devices and (100) channel bodies for NMOS devices. For example, the channel bodies for PMOS devices comprise silicon having the crystalline orientation of (110) and the channel bodies for NMOS devices comprise silicon having the crystalline orientation of (100).

In an example, individual ones of the GAA PMOS and NMOS devices can be a nanoribbon transistor, where the channel bodies comprise nanoribbons. However, as will be further appreciated in light of this disclosure, reference to nanoribbons is also intended to include other gate-all-around channel regions, such as nanowires, nanosheets, and other such semiconductor bodies around which a gate structure can wrap. To this end, the use of a specific channel region configuration (e.g., nanoribbon) is not intended to limit the present description to that specific channel configuration. Rather, the techniques provided herein can benefit any number of channel configurations, whether those bodies be nanowires, nanoribbons, nanosheets, or some other channel configurations where the gate structure partially wraps around a channel body, such as a forksheet device.

In some embodiments, the GAA structure comprises one or more NMOS devices having (100) channel bodies and one or more PMOS device having (110) channel bodies. In one such embodiment, the GAA structure specifically comprises (i) two NMOS devices having (100) channel bodies and (ii) one PMOS device laterally between the two NMOS devices and having (110) channel bodies. Other combinations of NMOS and PMOS devices can also be envisioned.

In one embodiment, the GAA structure is formed over a hybrid base or substrate comprising both silicon (100) and silicon (110). Two example configurations of the substrate are discussed herein below.

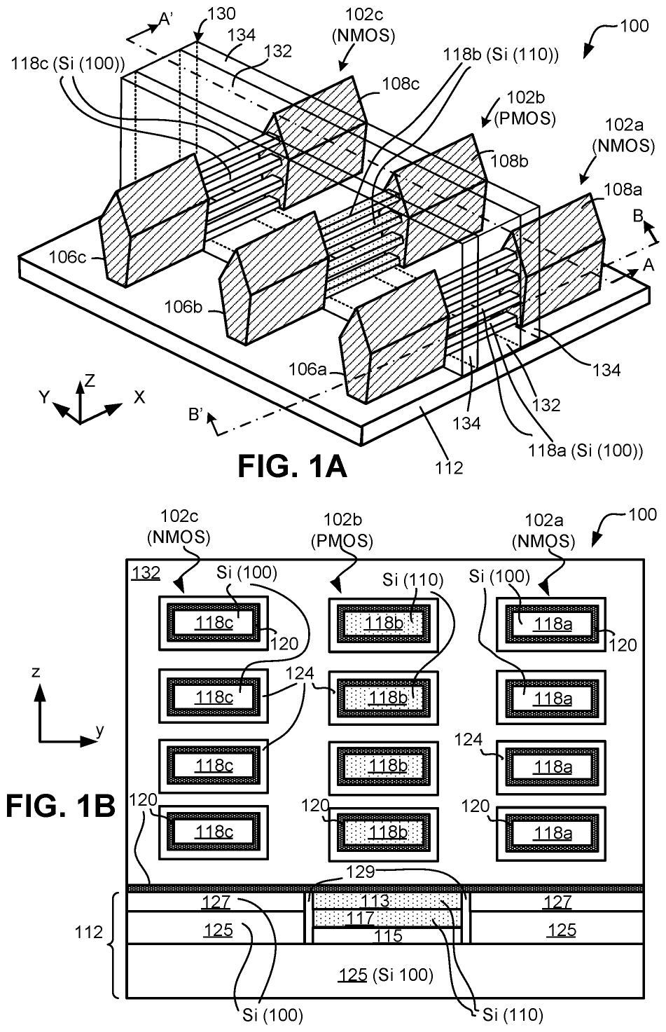

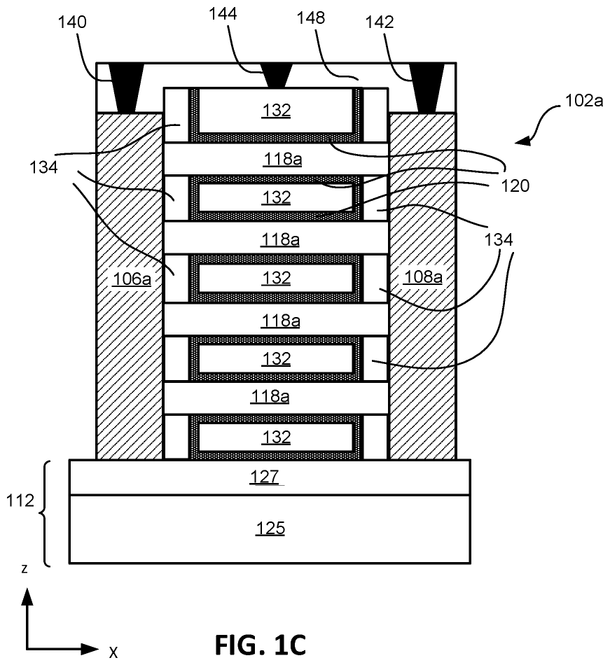

In a first example configuration of the substrate (e.g., as discussed with respect to FIGS. 1A-1B herein in turn), one or more NMOS devices are formed over a first section of the substrate, where the first section comprises silicon (100). One or more PMOS devices are formed over a second section of the substrate, where a top portion of the second section comprises silicon (110) and a bottom portion of the second section comprises silicon (100). In one such example, an insulator layer (e.g., comprising silicon oxide or another appropriate insulator material) is between the top portion of the second section and the bottom portion of the second section. Thus, the insulator layer vertically isolates the silicon (100) portion of the substrate and the silicon (110) portion of the substrate. One or more vertical spacers laterally isolate the silicon (100) portion of the substrate and the silicon (110) portion of the substrate.

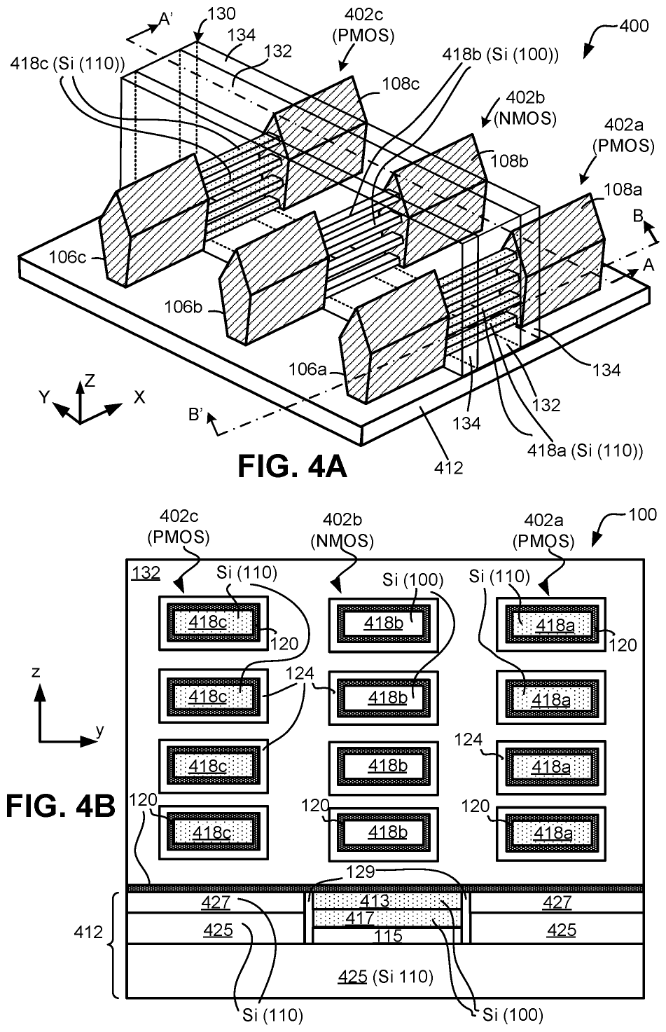

In a second example configuration of the substrate (e.g., as discussed with respect to FIGS. 4A-4B herein in turn), one or more PMOS devices are formed over a first section of the substrate, where the first section comprises silicon (110). One or more NMOS devices are formed over a second section of the substrate, where a top portion of the second section comprises silicon (100) and a bottom portion of the second section comprises silicon (110). In one embodiment, an insulator layer (e.g., comprising silicon oxide or another appropriate insulator material) is between the top portion of the second section and the bottom portion of the second section. Thus, the insulator layer vertically isolates the silicon (100) portion of the substrate and the silicon (110) portion of the substrate. One or more vertical spacers laterally isolate the silicon (100) portion of the substrate and the silicon (110) portion of the substrate.

In one embodiment, the GAA CMOS structure comprising a PMOS device with (110) channel body and an NMOS device with (100) channel body may be formed by forming a stack of alternating layers of sacrificial material and channel material above a substrate. The substrate may have one of the above discussed two example configurations. In an example, each layer of channel material in the stack comprises (i) a first section having silicon (110), and (ii) a second section having silicon (100). The stack is selectively etched, to define at least (i) a first fin having alternating layers of the silicon (110) and the sacrificial material, and (ii) a second fin having alternating layers of the silicon (100) and the sacrificial material. Subsequently, the GAA structure is processed to form dummy gate, and (i) a first source region and a first drain region, wherein the first fin is laterally between the first source region and the first drain region, and (ii) a second source region and a second drain region, wherein the second fin is laterally between the second source region and the second drain region. The dummy gate is then removed, and the sacrificial material from the first and second fins are then removed to release the channel bodies. Accordingly, (i) the layers of the silicon (110) of the first fin form a first plurality of bodies laterally between the first source region and the first drain region, and (ii) the layers of the silicon (100) of the second fin form a second plurality of bodies laterally between the second source region and the second drain region. A gate stack wrapping the first and second plurality of bodies are then completed.

In an example, the first source region, the first drain region, and the first plurality of bodies (comprising silicon 110) laterally between the first source region and the first drain region form a PMOS device. In an example, the second source region, the second drain region, and the second plurality of bodies (comprising silicon 100) laterally between the second source region and the second drain region form a NMOS device.

As previously discussed herein, performance between the PMOS device and the NMOS device are relatively better matched, e.g., due to hybrid usages of (110) and (100) for the channel bodies of the PMOS and NMOS devices, respectively. This improves overall performance of the CMOS circuits comprising the various PMOS and NMOS devices.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

In some embodiments, a plurality of channel layers of compositionally different channel materials or geometries may be formed on different areas of the substrate, such as for CMOS applications, for example. For instance, a first channel material layer may be formed on a first area of a silicon base to be used for one or more p-channel transistor devices (e.g., one or more PMOS devices) and a second channel material layer may be formed on a second area of the silicon base to be used for one or more n-channel transistor devices (e.g., one or more NMOS devices). As previously described, by selecting the substrate to have the desired material characteristics (e.g., the desired semiconductor material, the desired dopant concentration, and desired dopant type) the substrate can be used to grow multiple different channel layers.

Note that the use of “source/drain” herein is simply intended to refer to a source region or a drain region or both a source region and a drain region. To this end, the forward slash (“/”) as used herein means “and/or” unless otherwise specified, and is not intended to implicate any particular structural limitation or arrangement with respect to source and drain regions, or any other materials or features that are listed herein in conjunction with a forward slash.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may indicate a PMOS transistor with nanoribbons (or nanowires, or nanosheets, or other semiconductor body, as the case may be) comprising silicon (110) and an NMOS transistor with nanoribbons comprising silicon (100), where the PMOS and the NMOS transistors form a CMOS circuit. Furthermore, such tools may also be used to detect (i) a first section of the substrate, on which the PMOS transistor is formed, having a top portion comprising silicon (110), and (ii) a second section of the substrate, on which the NMOS transistor is formed, having a top portion comprising silicon (100). A bottom portion of the substrate may include either silicon (100) or silicon (110), where the silicon (100) and silicon (110) of the substrate may be laterally and vertically separated by corresponding spacers and/or other appropriate insulator materials.

Numerous configurations and variations will be apparent in light of this disclosure.

### Architecture and Methodology

FIG. 1A illustrates a perspective view of an example GAA semiconductor structure 100 (also referred to herein as “structure 100”), FIG. 1B illustrates a cross-sectional view of the GAA semiconductor structure 100, and FIG. 1C illustrates another cross-sectional view of the GAA semiconductor structure 100, where the GAA semiconductor structure 100 comprises (i) one or more P-channel metal-oxide-semiconductor (PMOS) devices with channel region(s) comprising semiconductor material with crystalline orientation described by a Miller index of (110) and (ii) one or more N-channel metal-oxide-semiconductor (NMOS) devices with channel region(s) comprising semiconductor material with crystalline orientation described by a Miller index of (100), in accordance with an embodiment of the present disclosure.

The cross-sectional view of FIG. 1B is along line A-A′ of FIG. 1A. That is, the cross-sectional view of FIG. 1B is along a gate electrode 132 of the structure 100, and this view is also referred to as a “gate-cut” view of the structure 100, which illustrates cross sectional view of various nanoribbons of various devices.

The cross-sectional view of FIG. 1C is along the line B-B′ of FIG. 1A, i.e., along the length of nanoribbons 118a of the device 102a, and entire length of the nanoribbons 118a of the device 102a are visible in FIG. 1C. Note that in the cross-sectional view of FIG. 1C, only the right-most GAA device 102a is visible.

FIGS. 1A, 1B illustrate three GAA devices (also referred to herein simply as devices) 102a, 102b, 102c, although the structure 100 can include any other appropriate number of such devices, such as one, two, four, or higher. In one embodiment, the devices 102a, 102b, 102c are nanoribbon transistor devices, although the devices can be any other type of GAA devices. As will be further appreciated in light of this disclosure, reference to nanoribbons is also intended to include other channel regions, such as nanowires or nanosheets, and other such semiconductor bodies around which a gate structure wraps around the channel region. To this end, the use of a specific channel region configuration (e.g., GAA) is not intended to limit the present description to that specific channel configuration. In an example, the teachings of this disclosure may also be applicable to devices in which the gate at least partially wrap around the channel region, such as forksheet transistors.

In one embodiment, at least two of the devices 102a, 102b, 102c are configured in a Complementary metal-oxide-semiconductor (CMOS) architecture. In an example, at least one of the devices 102a, 102b, 102c is complimentary to other ones of the devices 102a, 102b, 102c. Merely as an example, the devices 102a, 102c can be PMOS devices and the device 102b can be an NMOS device. In another example, the devices 102a, 102c can be NMOS devices and the device 102b can be a PMOS device. Any other combination may also be possible. Merely for purposes of discussion herein and without limiting the scope of this disclosure, it is assumed that the devices 102a, 102c are NMOS devices and the device 102b is a PMOS device.

In one embodiment, individual devices 102 (e.g., devices 102a, 102b, 102c) comprise a plurality of nanoribbons 118 (or nanowires, or nanosheets, as the case may be). For example, device 102a comprises a vertical stack of four nanoribbons 118a, device 102b comprises a vertical stack of four nanoribbons 118b, and device 102c comprises a vertical stack of four nanoribbons 118c. The number of nanoribbons 118 in each device 102 (i.e., four nanoribbons per device) is merely an example, and an individual device 102 can comprises a different number of nanoribbons, such as one, two, three, five or higher number of nanoribbons.

In one embodiment, the nanoribbons 118a and 118c of the NMOS devices 102a and 102c, respectively, comprise semiconductor material with crystalline orientation described by a Miller index of (100). In one embodiment, the nanoribbons 118b of the PMOS device 102b comprises semiconductor material with crystalline orientation described by a Miller index of (110). In an example, the semiconductor material of the nanoribbons 118a, 118b, 118c comprise silicon.

For purposes of simplicity, nanoribbon material with crystalline orientation described by a Miller index of (100) is referred to herein as silicon (100), and nanoribbon material with crystalline orientation described by a Miller index of (110) is referred to herein as silicon (110). Thus, silicon (100) or Si (100) implies silicon with crystalline orientation described by a Miller index of (100). Similarly, silicon (110) or Si (110) implies silicon with crystalline orientation described by a Miller index of (110).

Thus, the nanoribbons 118a and 118c of the NMOS devices 102a and 102c, respectively, comprise Si (100) (illustrated using solid white color in FIGS. 1A and 1B), and the nanoribbons 118b of the PMOS device 102b comprise Si (110) (illustrated using dotted region in FIGS. 1A and 1B).

Use of Si (110) in the nanoribbons 118b increases carrier (e.g., hole) mobility in the nanoribbons 118b of the PMOS device 102b, which in turn improves the performance of the PMOS device 102b. Furthermore, using Si (100) in the nanoribbons 118a, 118c does not reduce the carrier (e.g., electron) mobility in the nanoribbons 118a, 118c of the NMOS devices 102a, 102c. Accordingly, matching of performance between the PMOS device 102b and the NMOS devices 102a, 102c increases, e.g., due to selective usages of Si (110) and Si (100) for the nanoribbons of the PMOS and NMOS devices, respectively. This improves overall performance of the CMOS circuits comprising the various PMOS and NMOS devices, and also improves overall performance of the structure 100.

In one embodiment, the nanoribbons 118 are appropriately doped. As an example, the nanoribbons 118b of the PMOS device 102b are doped with n-type dopants (e.g., phosphorous or arsenic), and the nanoribbons 118a, 118c of the NMOS devices 102a, 102c are doped with p-type dopants (e.g., boron).

Although in FIGS. 1A-1B the nanoribbons 118 extend horizontally and are stacked vertically, the present disclosure contemplates nanoribbons in a variety of configurations that include planar nanoribbon transistors, nanoribbons that extend vertically and are stacked horizontally, and other arrangements, as will be appreciated.

As illustrated in FIGS. 1A and 1C, for each device 102, the corresponding nanoribbon channel region extends between and connects corresponding source region 106 and corresponding drain region 108, where the channel region includes the one or more nanoribbons 118 that extend horizontally and are arranged in a vertical stack. For example, as illustrated in FIG. 1C, device 102a comprises source region 106a and drain region 108a, with the nanoribbons 118a extending horizontally and arranged in a vertical stack between the source region 106a and drain region 108a. Similarly, although not illustrated in FIGS. 1B and 1C (but illustrated in FIG. 1A), device 102b comprises source region 106b and drain region 108b, with the nanoribbons 118b extending horizontally and arranged in a vertical stack between the source region 106b and drain region 108b. Similarly, device 102c comprises source region 106c and drain region 108c, with the nanoribbons 118c extending horizontally and arranged in a vertical stack between the source region 106c and drain region 108c. Note that the various source regions 106 and the drain regions 108 are visible in the perspective view of FIG. 1A, but are not visible in the cross-sectional gate-cut view of FIG. 1B.

According to some embodiments, the source and drain regions 106, 108 are epitaxial regions that are provided using an etch-and-replace process. In other embodiments one or both of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. Any semiconductor materials suitable for source and drain regions can be used (e.g., group IV and group III-V semiconductor materials).

Although not illustrated in FIGS. 1A and 1B for purposes of illustrative simplicity and illustrated in FIG. 1C, in some embodiments, conductive contacts are formed over source and drain regions 106, 108 and gate electrode 132 of each of the devices 102a, 102b, 102c. For example, FIG. 1C illustrates, for the device 102a, conductive source contacts 140 extending through an Interlayer Dielectric Layer (ILD) 148 and contacting the source region 106a, conductive drain contacts 142 extending through the ILD 148 and contacting the drain region 108a, and conductive gate contacts 144 extending through the ILD 148 and contacting the gate electrode 132. The conductive contacts may be any suitably conductive material. In some embodiments, conductive contacts include one or more of the same metal materials as gate electrode, or a different conductive material.

A gate structure 130 contacts and surrounds the nanoribbons 118 between the source and drain regions 106, 108. Note that the gate structure of FIG. 1A is illustrated as being transparent in order to show the geometry of the nanoribbons 118. However, the illustration is not limiting and the materials used to form the gate structure are not necessarily transparent.

In one embodiment, the gate structure 130 includes a gate dielectric 120 (not illustrated in FIG. 1A but illustrated in FIGS. 1B and 1C) that wraps around middle section of each nanoribbon 118, and a gate electrode 132 that wraps around the gate dielectric 120. Note that the middle section of each nanoribbon 118 is between a corresponding first tip region and a second tip region, where the first tip region is between a first gate spacer 134 and the second tip region is between a second gate spacer 134. In an example, the gate electrode 132 may include any sufficiently conductive material, such as a metal, metal alloy, or doped polysilicon. The gate dielectric 120 may include a single material layer or multiple stacked material layers. In some embodiments, gate dielectric 120 includes a first dielectric layer such as silicon oxide, and a second dielectric layer that includes a high-K material such as hafnium oxide. The hafnium oxide may be doped with an element to affect the threshold voltage of the given semiconductor device. According to some embodiments, the doping element used in gate dielectric 120 is lanthanum. The combination of gate dielectric 120 and gate electrode 132 forms a gate structure for each of semiconductor devices 102a, 102b, 102c.

Although not illustrated in FIG. 1A, in one embodiment, the gate electrode 132 may be interrupted between any adjacent devices 102 by a gate cut structure. In such an embodiment, individual devices 102a, 102b, 102c may have corresponding separate gate electrodes. In some other embodiments, the same continuous gate electrode 132 wraps around nanoribbons of at least two adjacent ones of the devices 102a, 102b, 102c.

In an example, the middle regions of individual nanoribbons are wrapped by the gate dielectric 120 and the gate electrode 132 (see FIG. 1C). In an example, due to conformal deposition of the gate dielectric 120, the gate dielectric 120 may also be present on inner walls of the gate spacers 134 and on top surface of a substrate or base 112, as seen in FIG. 1C.

In one embodiment, one or more work function metals 124 may be included around the nanoribbons 118, as illustrated in FIG. 1B (note that the work function metals 124 are not illustrated in FIGS. 1A and 1C, for purposes of illustrative clarity). In some embodiments, the PMOS device 102b may include a work function metal having titanium, and the NMOS devices 102a, 102c may include a work function metal having tungsten. In some other embodiments, the work function metal may be absent around one or more nanoribbons 118.

The gate structure 130 also includes gate spacers 134 that extend along the sides of the gate electrode 132, to isolate the gate electrode 132 from the source and drain regions 106, 108. The gate spacers 134 at least partially surround the tip regions of the nanoribbons 118 (e.g., see FIG. 1C) and are located between the gate electrode 132 and the source and drain regions 106, 108. For example, FIG. 1C illustrates the gate spacers 134 between the gate electrode 132 and the corresponding source region 106a, and also between the gate electrode 132 and the corresponding drain region 108a. In one embodiment, gate spacers 134 may include a dielectric material, such as silicon nitride.

As can be seen, the structure 100 is formed on a substrate or base 112. The substrate or base 112 comprises various sections, such as sections 117, 125, 127, and 113. In an example, the devices 102a, 102c are NMOS devices having Si (100) nanoribbons and the device 102b is a PMOS device having Si (110) nanoribbons, and the section 125 comprises Si (100). In an example, sections 127 of the base 112 (see FIG. 1B) also comprises Si (100). As illustrated, sections 127 are below the NMOS devices 102a, 102c. For example, sections 127 are within subfin regions of the NMOS devices 102a, 102c. As illustrated, section 113 of the base 112 is below the PMOS device 102b, and section 117 of the base 112 is also below the PMOS device 102b. In one embodiment, sections 113 and 117 of the base 112 comprise Si (110).

In one embodiment, the sections 127 and 113 are appropriately doped, e.g., to achieve isolation between the gate electrode 132 and the sections 117, 125. The doping of the sections 127, 113 can be performed through ion implantation, for example. In an example, sections 127 are originally a part of the section 125 (e.g., both sections 125, 127 comprise Si (100)), but have a different doping profile relative to the section 125. Similarly, in an example, section 113 is originally a part of the section 117 (e.g., both sections 113, 117 comprise Si (110)), but have a different doping profile relative to the section 117. As discussed, the doping profile of the sections 113, 127 provides isolation between the gate electrode 132 and the substrate 112.

In one embodiment, a layer 115 comprising insulator or dielectric material (e.g., an oxide material, such as silicon dioxide) separates the section 125 from the section 117. Thus, the insulator or dielectric material of the layer 117 is sandwiched between the silicon layers 117, 125, e.g., in a buried oxide (BOX) structure. In one embodiment, the base 112 further comprises spacers 129, which comprise dielectric material such as silicon nitride or another appropriate dielectric material. In an example, the spacers 129 separate and isolate the Si (100) sections 125, 127 from the Si (110) sections 113, 117.

In some embodiments, the sections 125, 117 may be doped with any suitable n-type and/or p-type dopant at a dopant concentration in the range of 1E16 to 1E22 atoms per cubic cm, for example. For instance, a silicon base can be p-type doped using a suitable acceptor (e.g., boron) or n-type doped using a suitable donor (e.g., phosphorous, arsenic) with a doping concentration of at least 1E16 atoms per cubic cm. However, in some embodiments, the base may be undoped/intrinsic or relatively minimally doped (such as including a dopant concentration of less than 1E16 atoms per cubic cm), for example. In some embodiments, the sections 125, 117 are silicon substrates consisting essentially of Si, with silicon orientation discussed herein earlier. In other embodiments, the sections 125, 117 may primarily include Si but may also include other material (e.g., a dopant at a given concentration). Also, note that the base material may include relatively high quality or device-quality monocrystalline Si or other material that provides a suitable template or seeding surface from which other monocrystalline semiconductor material features and layers can be formed. In some embodiments, the sections 117, 125 may have a crystalline orientation described by a Miller index of (110) and (100), respectively, as discussed herein. Although the substrate in this example embodiment are shown for ease of illustration as having a thickness (dimension in the Z-axis direction) somewhat similar to that of other layers in the figures, the substrate may be relatively much thicker than the other layers, such as having a thickness in the range of 1 to 950 microns (or in the sub-range of 20 to 800 microns), for example, or any other suitable thickness or range of thicknesses as will be apparent in light of this disclosure. In some embodiments, the structures described herein may be included in a system-on-chip (SoC) application, as will be apparent in light of this disclosure.

As discussed, in an example, the nanoribbons 118a and 118c of the NMOS devices 102a and 102c, respectively, comprise Si (100), and the nanoribbons 118b of the PMOS device 102b comprise Si (110). In another example, one or more nanoribbons of the devices 102a, 102b, and/or 102c can have a different crystalline orientation, such as crystalline orientation described by a Miller index of, for example, (111).

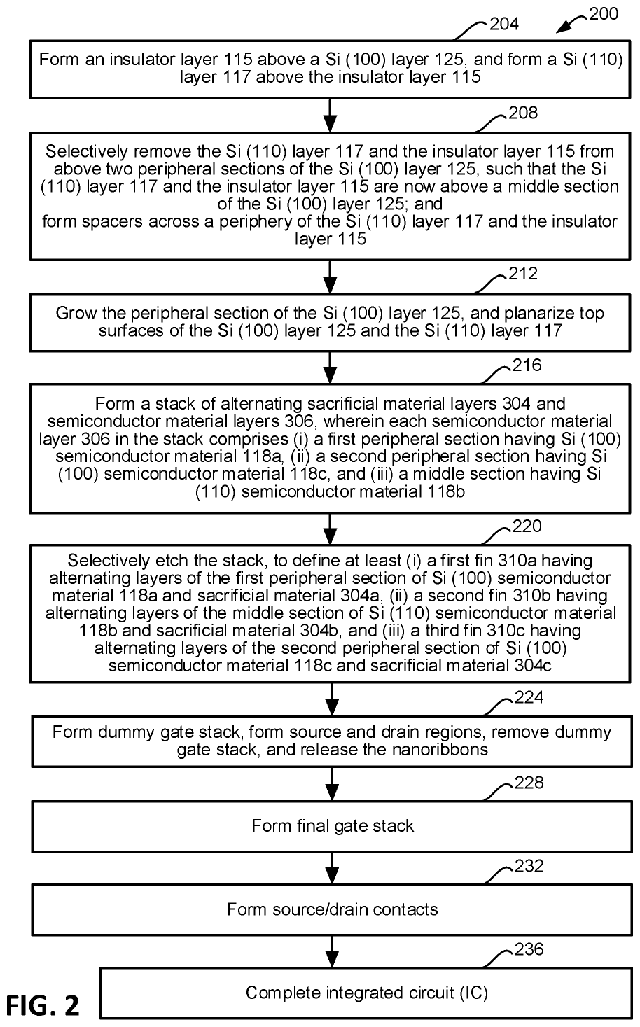

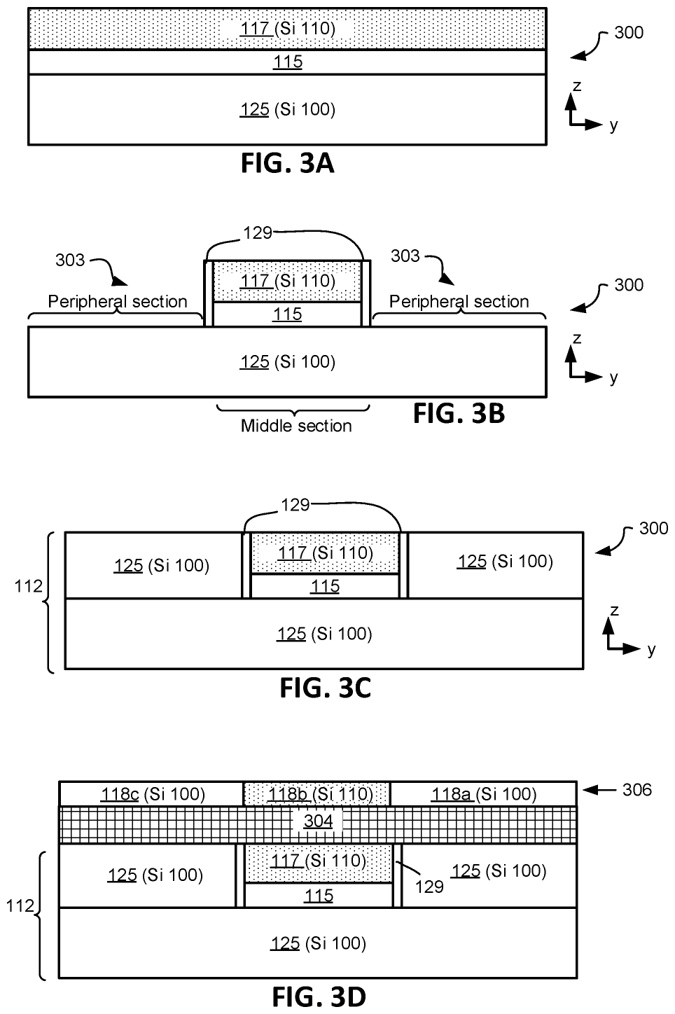

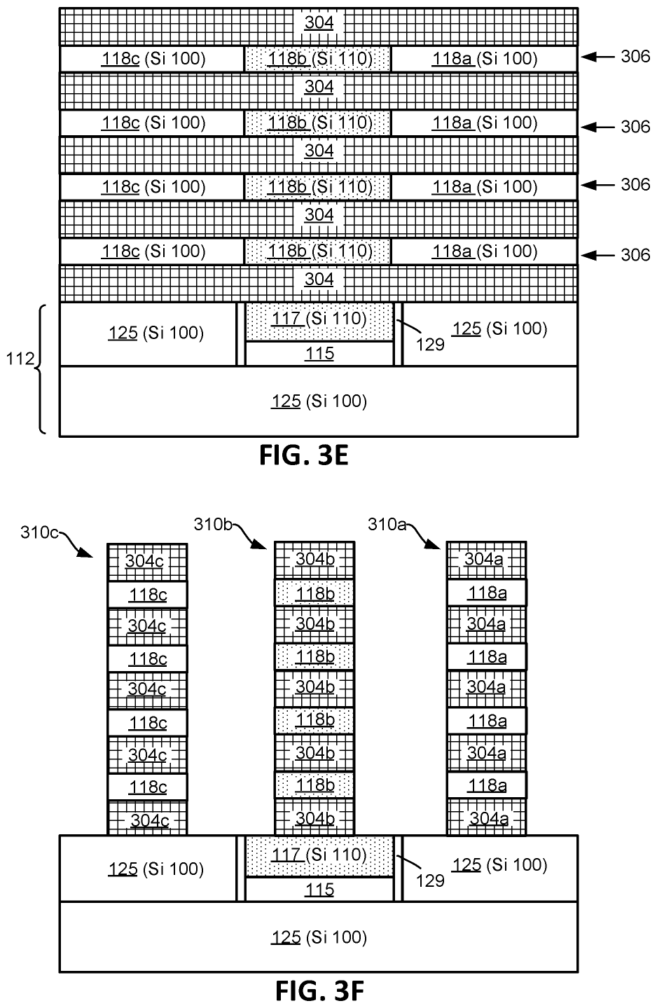

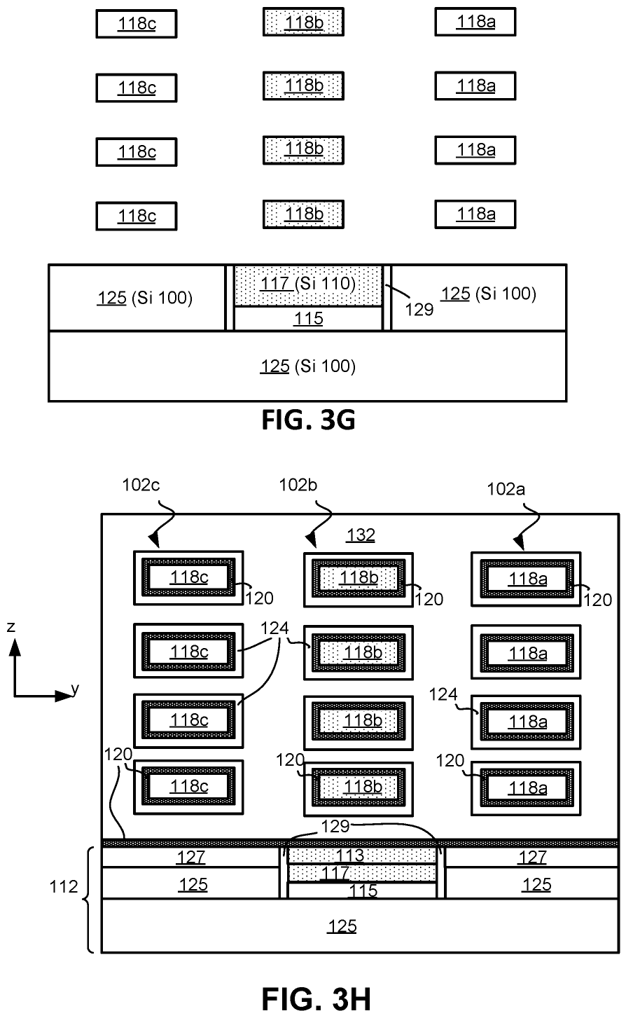

FIG. 2 illustrates a flowchart depicting a method 200 of forming a GAA semiconductor structure (such as the GAA semiconductor structure of FIGS. 1A-1C), where the GAA semiconductor structure comprises (i) one or more P-channel metal-oxide-semiconductor (PMOS) devices with channel region(s) comprising semiconductor material with crystalline orientation described by a Miller index of (110) and (ii) one or more N-channel metal-oxide-semiconductor (NMOS) devices with channel region(s) comprising semiconductor material with crystalline orientation described by a Miller index of (100), in accordance with an embodiment of the present disclosure. FIGS. 3A-3H collectively illustrate cross-sectional views of an example GAA semiconductor structure (e.g., the GAA semiconductor structure of FIGS. 1A-1C and 2) in various stages of processing, in accordance with an embodiment of the present disclosure. FIGS. 2 and 3A-3H will be discussed in unison. In FIGS. 3A-3H, the cross-sectional views are along line A-A′ of FIG. 1A (e.g., similar to FIG. 1B).

Referring to FIG. 2, the method 200 includes, at 204, forming an insulator layer 115 above a Si (100) layer 125, and subsequently forming a Si (110) layer 117 above the insulator layer 115. For example, FIG. 3A illustrates the Si (110) layer 117 above the insulator layer 115, which is above the Si (100) layer 125. The various layers may be formed using an appropriate deposition process, such as chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example. The insulator layer 115 is sandwiched between the two Si layers. The insulator layer 115 is a buried oxide layer (BOX) in an example. For example, the insulator layer 115 is an oxide layer, such as SiO2, although another appropriate insulator layer may also be used.

Referring again to the method 200 of FIG. 2, the method 200 proceeds from 204 to 208. At 208, the Si (110) layer 117 and the insulator layer 115 are selectively removed from above two peripheral sections of the Si (100) layer 125, such that the Si (110) layer 117 and the insulator layer 115 are above a middle section of the Si (100) layer 125. For example, FIG. 3B illustrates the Si (110) layer 117 and the insulator layer 115 above the middle section of the Si (100) layer 125. The removal can be performed using an appropriate anisotropic etching technique. The removal results in formation of recessed regions 303 above the peripheral sections of the Si (100) layer 125, as illustrated in FIG. 3B.

At 208, the method 200 also comprises forming spacers 129 across a periphery of the recessed Si (110) layer 117 and the insulator layer 115. FIG. 3B also illustrates the spacers 129 across a periphery of the recessed Si (110) layer 117 and the insulator layer 115. The spacers 129 may be formed using an appropriate deposition technique, such as CVD, PVD, ALD, VPE, MBE, or LPE, for example.

Referring again to the method 200 of FIG. 2, the method 200 proceeds from 208 to 212. At 212, the peripheral section of the Si (100) layer 125 is grown. For example, FIG. 3C illustrates the growing of the peripheral section of the Si (100) layer 125. In an example, the peripheral section of the Si (100) layer 125 is grown in the recessed regions 330 of FIG. 3B. Subsequently, top surfaces of the Si (100) layer 125 and the Si (110) layer 117 are planarized, such that the top surfaces of the Si (100) layer 125 and the Si (110) layer 117 are coplanar or flush. The planarization is performed using a suitable technique, such as chemical mechanical polishing (CMP) or mechanical polishing, for example.

Referring again to the method 200 of FIG. 2, the method 200 proceeds from 212 to 216. At 216, a stack of alternating sacrificial material layers 304 and channel material layers 306 is formed, as also illustrated in FIGS. 3D and 3E. In one embodiment, each channel material layer 306 in the stack comprises (i) a first peripheral section having Si (100) semiconductor material 118a, (ii) a second peripheral section having Si (100) semiconductor material 118c, and (iii) a middle section having Si (110) semiconductor material 118b. As illustrated in FIGS. 3D and 3E, for each channel material layer 306, the middle section having Si (110) semiconductor material 118b is laterally between the first and second peripheral sections.

In an example, the sacrificial material layers 304 comprising SiGe. The sacrificial material layer 304 is etch selective to the channel material layer 306, e.g., such that the sacrificial material layer 304 can be later etched and removed (e.g., during nanoribbon release process), without substantially etching the channel material layer 306.

For example, FIG. 3D illustrates formation of a first sacrificial material layer 304 and a first channel material layer 306. After the first channel material layer 306 is formed, a top surface of the channel material layer 306 may be planarized, such that the top surfaces of the two peripheral sections and the middle section are coplanar and flush. The planarization is performed using a suitable technique, such as CMP or mechanical polishing, for example. This process is repeated for subsequent channel material layers 306 as well, as illustrated in FIG. 3E. Individual ones of the sacrificial material layers 304 and the channel material layers 306 of the stack is formed using an appropriate deposition or epitaxial growth technique, such as CVD, PVD, ALD, VPE, MBE, or LPE, for example.

Note that the different areas of the channel material layers 306 may be formed using different crystalline orientation of Si using any suitable techniques, such as masking, depositing, and removing the masking, as desired, to form any number of orientationally different sections of a channel material layer 306.

In some embodiments, a given layer of channel material 306 may include a vertical channel height (dimension in the Z-axis direction) in the range of 5 nm to 50 nm (or in a subrange of 5-45, 5-40, 5-35. 5-30. 5-25, 5-20, 5-15, 5-10, 10-40, 10-30, 10-20, 15-40, 15-30, 15-20, 20-40, 20-30 and 30-40 nm) and/or a maximum vertical thickness of at most 50, 40, 30, 25, 20, 15, or 10 nm, for example. Other suitable materials and channel height requirements or thresholds will be apparent in light of this disclosure.

In some embodiments, the channel material layer 306 may be doped differently on different areas, such as for CMOS applications, for example. For instance, the first peripheral section having Si (100) semiconductor material 118a and the second peripheral section having Si (100) semiconductor material 118c may be doped appropriately for a n-channel transistor device (e.g., for NMOS devices 102a, 102c). The middle section having Si (110) semiconductor material 118b may be doped appropriately for a p-channel transistor device (e.g., for PMOS 102b). Thus, the doping profile of each section of the layers of channel material 306 may be based on whether the section is to be eventually used to form a nanoribbon for a PMOS device or for an NMOS device. Note that the different areas of the layers channel materials 306 may be doped differently using any suitable techniques, such as masking, doping, and removing the masking, as desired, to form any number of compositionally different doped channel materials. Numerous different channel material doping configurations and variations will be apparent in light of this disclosure.

Referring again to the method 200 of FIG. 2, the method 200 proceeds from 216 to 220. At 220, the stack is selectively etched, to define at least (i) a first fin 310a having alternating layers of the first peripheral section of Si (100) semiconductor material 118a and sacrificial material 304a, (ii) a second fin 310b having alternating layers of the middle section of Si (110) semiconductor material 118b and sacrificial material 304b, and (iii) a third fin 310c having alternating layers of the second peripheral section of Si (100) semiconductor material 118c and sacrificial material 304c, as illustrated in FIG. 3F.

In one embodiment, etching the various layers 304, 306 to define the fins 310a, 310b, 310c can be performed using any suitable techniques for etching and defining fins. For example, regions to be processed into the fins 310a, 310b, 310c are masked, followed by etching the surrounding regions to define the fins. For instance, an anisotropic etch proceeds substantially vertically through the upper fin portion to define isolation trenches between adjacent fins.

In some embodiments, each fin may include a vertical fin height (dimension in the Z-axis direction) in the range of 20-500 nm (or in a subrange of 20-50, 20-100, 20-200, 20-300, 20-400, 50-100, 50-200, 50-300, 50-400, 50-500, 100-250, 100-400, 100-500, 200-400, or 200-500 nm) and/or a maximum vertical fin height of at most 500, 450, 400, 350, 300, 250, 200, 150, 100, or 50 nm, for example. In some embodiments, each fin may include a horizontal fin width (dimension in the x-axis direction) in the range of 2-50 nm (or in a subrange of 2-5, 2-10, 5-10, 5-20, 5-30, 5-50, 10-20, 10-30, 10-50, 20-30, 20-50, or 30-50 nm) and/or a maximum horizontal fin width of at most 50, 30, 20, 10, or 5 nm, for example. In some embodiments, the ratio of fin height to fin width may be greater than 1, such as greater than 1.5, 2, 2.5, 3, 3.5, 4, 4.5, 5, 6, 7, 8, 9, 10, 15, 20, or greater than any other suitable threshold ratio, as will be apparent in light of this disclosure. Other suitable materials and thickness values/ranges/thresholds will be apparent in light of this disclosure.

Referring again to the method 200 of FIG. 2, the method 200 proceeds from 220 to 224. At 224, for each of the fins 310a, 310b, 310c, corresponding dummy gate stack is formed, followed by formation of corresponding source region 106 and drain region 108, and then the dummy gate stack is removed. After removing of the dummy gate, the nanoribbons of individual fins are released, e.g., by selectively etching the sacrificial materials 304 from each of the fins 310a, 310b, 310c.

In an example, the dummy gate structure comprises dummy gate electrode (not illustrated in the figures), which may comprise poly-Si, for example. Gate spacers 134 (see FIG. 1C) are formed along opposite sides of the dummy gate electrode. For example, the gate spacers 134 comprise silicon nitride (Si₃N₄) or other suitable material, as will be appreciated.

The source region and the drain region of individual devices 102a, 102b, 102c can be formed using any suitable techniques, in accordance with an embodiment of the present disclosure. For example, processing the source and drain regions can be performed by etching at least a portion of the exposed source and drain portion of the fins to remove the layer stack, and forming replacement source and drain material using any suitable techniques, such as CVD, PVD, ALD, VPE, MBE, or LPE, for example. In some embodiments, the exposed source/drain regions of the fins need not be completely removed; instead, the material in the layer stack at the source/drain regions is converted to final source/drain regions by doping, implantation, and/or cladding with a source/drain material or other suitable processing, for example.

In some embodiments, the source and drain regions may be formed one polarity at a time, such as performing processing for one of n-type and p-type regions, and then performing processing for the other of the n-type and p-type regions. For example, the devices 102a and 102c are NMOS devices, and hence, the source and drain regions 106a, 108a of the device 102a and the source and drain regions 108c, 108c of the device 102c may be formed at the same time, followed by formation of the source and drain regions 108b, 108b of the PMOS device 102b. In some embodiments, the source and drain regions may include any suitable doping scheme, such as including suitable n-type and/or p-type dopant (e.g., in a concentration in the range of 1E16 to 1E22 atoms per cubic cm), depending on the device for which the source and drain regions are formed. However, in some embodiments, at least one source or drain region may be undoped/intrinsic or relatively minimally doped, such as including a dopant concentration of less than 1E16 atoms per cubic cm, for example.

As discussed, also at 220, the nanoribbons are released in the channel region, as also illustrated in FIG. 3G. Releasing the nanoribbons involve removing the dummy gate oxide and the dummy gate electrode between the gate spacers 134, to expose the channel region of the fin. For example, a polycrystalline silicon dummy gate electrode can be removed using a wet etch process (e.g., nitric acid/hydrofluoric acid), an anisotropic dry etch, or other suitable etch process, as will be appreciated. At this stage of processing, for each fin, the layer stack of alternating layers of channel material 306 and sacrificial material 304 is exposed in the channel region. The channel region extends between and contacts the source and drain regions, where tip regions of the layer stack are protected by the gate spacers. The sacrificial material 304 in the various fins can then be removed by etch processing, in accordance with some embodiments.

Etching the sacrificial material 304 may be performed using any suitable wet or dry etching process such that the etch process selectively removes the sacrificial material and leaves intact the channel material of the nanoribbons 118a of the fin 310a, the nanoribbons 118b of the fin 310b, and the nanoribbons 118c of the fin 310c, as illustrated in FIG. 3G. In one embodiment, the sacrificial material is silicon germanium (SiGe) and the channel material is electronic grade silicon (Si) having appropriate crystalline orientation discussed herein previously. For example, a gas-phase etch using an oxidizer and hydrofluoric acid (HF) has shown to selectively etch SiGe in SiGe/Si layer stacks. In another embodiment, a gas-phase chlorine trifluoride (ClF3) etch is used to remove the sacrificial SiGe material. The etch chemistry can be selected based on the germanium concentration, nanoribbon dimensions, and other factors, as will be appreciated. After removing the SiGe sacrificial material 304, the resulting channel region includes (i) silicon (100) nanoribbons 118a (for the device 102a) extending between the source and drain regions 106a, 108a of the fin 310a, (ii) silicon (110) nanoribbons 118b (for the device 102b) extending between the source and drain regions 106b, 108b of the fin 310b, and (iii) silicon (100) nanoribbons 118c (for the device 102c) extending between the source and drain regions 106c, 108c of the fin 310c.

Referring again to FIG. 2A, the method 200 then proceeds from 224 to 228, where the final gate stack is formed. For example, FIG. 3H illustrates the devices 102a, 102b, 102c, with the gate stack formed, where the gate stack comprises gate dielectric material 120 wrapped around middle regions of individual nanoribbons 118a, 118b, 118c, and the gate electrode 132 around the gate dielectric 120. In an example, due to conformal deposition of the gate dielectric 120, the gate dielectric 120 may also be present on inner walls of the gate spacers 134 (as seen in FIG. 1C) and on a top surface of the base 112 (as seen in FIG. 3H).

In an example embodiment, the gate stack is formed using a gate-last fabrication flow, which may be considered a replacement gate or replacement metal gate (RMG) process. In embodiments utilizing a nanoribbon channel structure, the gate stack may substantially (or completely) surround each nanoribbon middle region portion, such as wrapping around at least 80, 85, 90, 95% or more of each nanoribbon. Processing the final gate stack includes depositing gate dielectric 120 on the exposed nanoribbon middle region in the channel region, followed by formation of a gate electrode 132 in contact with the gate dielectric 120.

Any suitable technique can be used for forming the replacement gate stack, including spin-coating or CVD deposition, for example. The gate dielectric may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. In some embodiments, the gate dielectric can be annealed to improve its quality when high-k dielectric material is used. The gate electrode may include a wide range of materials, such as polysilicon or various suitable metals or metal alloys, such as aluminum (Al), tungsten (W), titanium (Ti), tantalum (Ta), copper (Cu), titanium nitride (TiN), or tantalum nitride (TaN), for example.

In some embodiments, gate dielectric and/or gate electrode may include a multilayer structure of two or more material layers, for example. For instance, in some embodiments, a multilayer gate dielectric may be employed to provide a more gradual electric transition from the channel region to the gate electrode, for example. In some embodiments, the gate dielectric and/or gate electrode may include grading (e.g., increasing and/or decreasing) the content or concentration of one or more materials in at least a portion of the feature(s). In some embodiments, one or more additional layers may also be present in the final gate stack, such as one or more relatively high or low work function layers and/or other suitable layers. Note that the gate dielectric may also be used to form replacement gate spacers on one or both sides of the nanoribbon body, such that the gate dielectric is between the gate electrode and one or both gate spacers, for example. Numerous different gate stack configurations will be apparent in light of this disclosure.

In one embodiment, one or more work function metals (such as work function metals 124) may be included around the nanoribbons 118, as illustrated in FIG. 3H. In some embodiments, the PMOS device 102b may include a work function metal having titanium, and the NMOS devices 102a, 102c may include a work function metal having tungsten. In some other embodiments, the work function metal may be absent around one or more nanoribbons.

Note that FIG. 3H illustrates the base having the doped sections 127 and 113 (discussed previously with respect to FIGS. 1A-1C), where the doping of the substrate has not been discussed with respect to FIGS. 2 and 3A-3G. In an example, the sections 127, 113 may be appropriately doped (e.g., via ion implantation or another suitable process) after formation of the base 112 in FIG. 3C (e.g., after the process 212 of the method 200 of FIG. 2).

The method 200 of FIG. 2 then proceeds from 228 to 232, where source/drain contacts are formed. FIG. 1C illustrates the device 102a, with source contacts 140 and drain contacts 142 formed. Also, in FIG. 1C, an appropriate ILD 148 is deposited above the device 102a, and the source and drain contacts 140, 142 are formed through the ILD 148. Also illustrated is the gate contact 144 through the ILD 148. In an example, the various contacts for other devices 102b, 102c are similarly formed.

In some embodiments, the source and drain contacts can be formed using any suitable techniques, such as forming contact trenches in the ILD layer 148 above the respective source/drain regions, and then depositing metal or metal alloy (or other suitable electrically conductive material) in the trenches. In some embodiments, forming the source/drain contacts may include silicidation, germanidation, III-V-idation, and/or annealing processes, for example. In some embodiments, the source and drain contacts may include aluminum or tungsten, although any suitable conductive metal or alloy can be used, such as silver, nickel-platinum, or nickel-aluminum, for example. In some embodiments, one or more of the source and drain contacts may include a resistance reducing metal and a contact plug metal, or just a contact plug, for instance. Example contact resistance reducing metals include, for instance, nickel, aluminum, titanium, gold, gold-germanium, nickel-platinum, nickel aluminum, and/or other such resistance reducing metals or alloys. Example contact plug metals include, for instance, aluminum, copper, nickel, platinum, titanium, or tungsten, or alloys thereof, although any suitably conductive contact metal or alloy may be used. In some embodiments, additional layers may be present in the source and drain contact regions, such as adhesion layers (e.g., titanium nitride) and/or liner or barrier layers (e.g., tantalum nitride), if so desired. In some embodiments, a contact resistance reducing layer may be present between a given source or drain region and its corresponding source or drain contact, such as a relatively highly doped (e.g., with dopant concentrations greater than 1E18, 1E19, 1E20, 1E21, or 1E22 atoms per cubic cm) intervening semiconductor material layer, for example. In some such embodiments, the contact resistance reducing layer may include semiconductor material and/or impurity dopants based on the included material and/or dopant concentration of the corresponding source or drain region, for example.

The method 200 of FIG. 2 then proceeds from 232 to 236, where a general integrated circuit (IC) is completed, as desired, in accordance with some embodiments. Such additional processing to complete an IC may include back-end or back-end-of-line (BEOL) processing to form one or more metallization layers and/or to interconnect the transistor devices formed, for example. Any other suitable processing may be performed, as will be apparent in light of this disclosure.

Note that the processes in method 200 are shown in a particular order for ease of description. However, one or more of the processes may be performed in a different order or may not be performed at all (and thus be optional), in accordance with some embodiments. Numerous variations on method 200 and the techniques described herein will be apparent in light of this disclosure.

FIG. 4A illustrates a perspective view of another example GAA semiconductor structure 400 (also referred to herein as “structure 400”) and FIG. 4B illustrates a cross-sectional view of the GAA semiconductor structure 400, where the GAA semiconductor structure 400 comprises (i) two PMOS devices 402a, 402c each with channel regions comprising semiconductor material with crystalline orientation described by a Miller index of (110) and (ii) one NMOS device 402b with a channel region comprising semiconductor material with crystalline orientation described by a Miller index of (100), in accordance with an embodiment of the present disclosure.

The structure 400 of FIGS. 4A and 4B are at least in part similar to the structure 100 of FIGS. 1A and 1B, and similar components in the two structures are labelled similarly. In FIGS. 1A and 1B, two devices 102a and 102c on two ends of the structure were NMOS devices, and the middle device 102b was a PMOS device. In contrast, two end devices 402a and 402c of the structure 400 are PMOS devices having nanoribbons 418a and 418c, respectively, where the nanoribbons 418a and 418c comprise Si (110). Also, a middle device 402b of the structure 400 is a NMOS device having nanoribbons 418b, where the nanoribbons 418b comprise Si (100).

Section 425 and section 427 below the devices 402a and 402c comprise Si (110), and section 417 and section 413 comprise Si (100). Thus, bulk of the base 412 of the structure 400 comprise Si (100), and some section 417 of the base 412 of the structure 400 comprises Si (100). Thus, the orientation of the base 412 of the structure 400 is also different and opposite compared to the orientation of the base 112 of the structure 100. The previous relevant discussion with respect to FIGS. 1A-3H is equally applicable to forming the structure 400.

### Example System

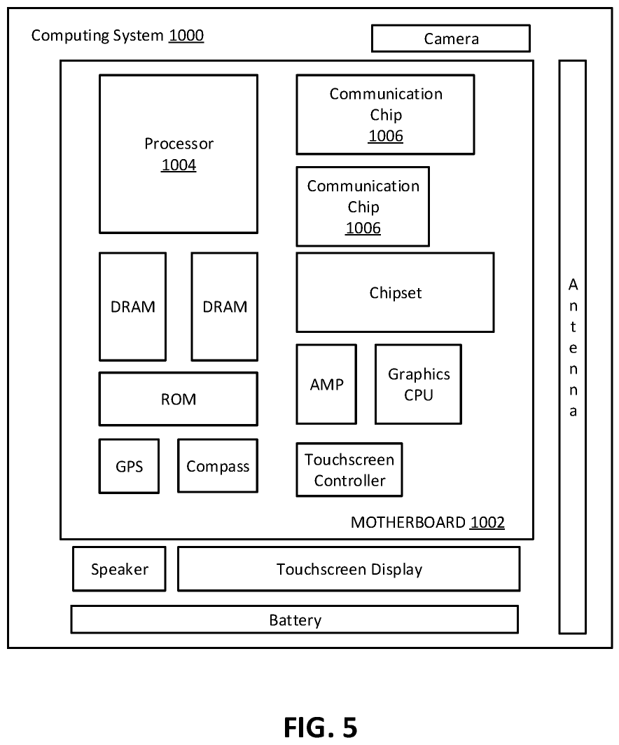

FIG. 5 illustrates a computing system 1000 implemented with integrated circuit structures and/or transistor devices formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### FURTHER EXAMPLE EMBODIMENTS

The following examples pertain to further embodiments, from which numerous permutations and configurations will be apparent.

Example 1. An integrated circuit structure comprising: a substrate; a first device above a first section of the substrate, the first device comprising a first source region and a first drain region, and a first body extending laterally between the first source and first drain regions, the first body comprising silicon with crystalline orientation described by Miller index of (100); and a second device above a second section of the substrate, the second device comprising a second source region and a second drain region, and a second body extending laterally between the second source and second drain regions, the second body comprising silicon with crystalline orientation described by Miller index of (110).

Example 2. The integrated circuit structure of example 1, wherein: the first section of the substrate, above which the first device is formed, comprises silicon with crystalline orientation described by Miller index of (100).

Example 3. The integrated circuit structure of any one of examples 1-2, wherein: a top portion of the second section of the substrate, above which the second device is formed, comprises silicon with crystalline orientation described by Miller index of (110); and a bottom portion of the second section of the substrate, above which the second device is formed, comprises silicon with crystalline orientation described by Miller index of (100).

Example 4. The integrated circuit structure of example 3, further comprising: a layer comprising insulator material between the top and bottom portions of the second section of the substrate.

Example 5. The integrated circuit structure of any one of examples 3-4, further comprising: a layer comprising oxygen between the top and bottom portions of the second section of the substrate.

Example 6. The integrated circuit structure of any one of examples 1-5, wherein the first device is a n-channel metal-oxide-semiconductor (NMOS) device, and the second device is a p-channel metal-oxide-semiconductor (PMOS) device.

Example 7. The integrated circuit structure of any one of examples 1-6, further comprising: a first gate structure at least in part wrapped around the first body, the first gate structure including (i) a first gate electrode and (ii) first gate dielectric between the first body and the first gate electrode; and a second gate structure at least in part wrapped around the second body, the second gate structure including (i) a second gate electrode and (ii) second gate dielectric between the second body and the second gate electrode.

Example 8. The integrated circuit structure of example 7, wherein: the first gate electrode and the second gate electrode form a continuous gate electrode structure.

Example 9. The integrated circuit structure of any one of examples 7-8, further comprising: a first spacer between the first gate electrode and the first source region, and a second spacer between the first gate electrode and the first drain region, wherein the first spacer is above and below a first tip region of the first body, and wherein the second spacer is above and below a second tip region of the first body.

Example 10. The integrated circuit structure of example 10, wherein the first and second spacers comprise silicon and nitrogen.

Example 11. The integrated circuit of any one of examples 1-10, wherein the first device comprises one or more additional bodies extending laterally between the first source and first drain regions, the one or more additional bodies comprising silicon with crystalline orientation described by Miller index of (100).

Example 12. The integrated circuit of any one of examples 10-11, wherein the first body and the one or more additional bodies are included in a vertical stack including two or more nanowires, nanoribbons, or nanosheets.

Example 13. The integrated circuit of any one of examples 1-12, wherein the second device comprises one or more additional bodies extending laterally between the second source and second drain regions, the one or more additional bodies comprising silicon with crystalline orientation described by Miller index of (110).

Example 14. The integrated circuit of example 13, wherein the second body and the one or more additional bodies are included in a vertical stack including two or more nanowires, nanoribbons, or nanosheets.

Example 15. The integrated circuit structure of any one of examples 1-14, wherein the first body is a nanoribbon, or a nanosheet.

Example 16. The integrated circuit structure of any one of examples 1-15, wherein one or both the first and second devices is a gate-all-around device.

Example 17. The integrated circuit structure of any one of examples 1-16, wherein one or both the first and second devices is a gate-all-around transistor.

Example 18. The integrated circuit structure of any one of examples 1-17, wherein one or both the first and second non-planar semiconductor devices is a forksheet transistor.

Example 19. An integrated circuit structure comprising: a first source region and a first drain region; a first body comprising first semiconductor material and extending laterally between the first source and first drain regions; a second source region and a second drain region; and a second body comprising second semiconductor material and extending laterally between the second source and second drain regions, wherein a first crystalline orientation of the first semiconductor material is different from a second crystalline orientation of the second semiconductor material.

Example 20. The integrated circuit structure of example 19, wherein: the first crystalline orientation is described by a Miller index of one of (110), (100), and (111); and the second crystalline orientation is described by a Miller index of another of (110), (100), and (111).

Example 21. The integrated circuit structure of any one of examples 19-20, wherein: the first source region, the first drain region, and the first body form a n-channel metal-oxide-semiconductor (NMOS) device, and the first crystalline orientation is described by a Miller index of (100); and the second source region, the second drain region, and the second body form a p-channel metal-oxide-semiconductor (PMOS) device, and the second crystalline orientation is described by a Miller index of (110).

Example 22. The integrated circuit structure of any one of examples 19-21, wherein each of the first body or the second body is a nanoribbon, a nanowire, or a nanosheet.

Example 23. The integrated circuit structure of any one of examples 19-22, further comprising: a substrate having (i) a first section, the first body above the first section, and (ii) a second section, the second body above the second section, wherein the first section of the substrate comprises semiconductor material having the first crystalline orientation.

Example 24. The integrated circuit structure of example 23, wherein: a top portion of the second section of the substrate comprises semiconductor material having the second crystalline orientation; and a bottom portion of the second section of the substrate comprises semiconductor material having the first crystalline orientation.

Example 25. The integrated circuit structure of example 24, further comprising: a layer comprising insulator material between the top and bottom portions of the second section of the substrate.

Example 26. The integrated circuit structure of any one of examples 24-25, further comprising: a layer comprising oxygen between the top and bottom portions of the second section of the substrate.

Example 27. A method of forming an integrated circuit structure, comprising: forming a stack of alternating layers of sacrificial material and channel material above a substrate, wherein each layer of channel material in the stack comprises (i) a first section having a first semiconductor material with a first crystalline orientation, and (ii) a second section having a second semiconductor material with a second crystalline orientation; selectively etching the stack to define at least (i) a first fin having alternating layers of the first semiconductor material with the first crystalline orientation and the sacrificial material, and (ii) a second fin having alternating layers of the second semiconductor material with the second crystalline orientation and the sacrificial material; forming (i) a first source region and a first drain region, such that the first fin is laterally between the first source region and the first drain region, and (ii) a second source region and a second drain region, such that the second fin is laterally between the second source region and the second drain region; and removing the sacrificial material from the first and second fins, such that (i) the layers of the first semiconductor material with the first crystalline orientation of the first fin form a first plurality of bodies laterally between the first source region and the first drain region, and (ii) the layers of the second semiconductor material with the second crystalline orientation of the second fin form a second plurality of bodies laterally between the second source region and the second drain region.

Example 28. The method of example 27, wherein the first crystalline orientation is described by a Miller index of one of (110), (100), and (111), and the second crystalline orientation is described by a Miller index of another of (110), (100), and (111).

Example 29. The method of any one of examples 27-28, wherein the first crystalline orientation is described by a Miller index of (110), and the second crystalline orientation is described by a Miller index of (100).

Example 30. The method of any one of examples 27-29, wherein: the first source region, the first drain region, and the first plurality of bodies laterally between the first source region and the first drain region form a p-channel metal-oxide-semiconductor (PMOS) device, and the first crystalline orientation is described by a Miller index of (110); and the second source region, the second drain region, and the second plurality of bodies laterally between the second source region and the second drain region form a n-channel metal-oxide-semiconductor (NMOS) device, and the second crystalline orientation is described by a Miller index of (100).

Example 31. The method of any one of examples 27-30, further comprising forming the substrate, wherein forming the substrate comprises: forming a first layer of the first semiconductor material with the first crystalline orientation above a second layer of the second semiconductor material with the second crystalline orientation; selectively removing the first layer from above a first section of the second layer, to generate a recess over the first section of the second layer, such that the first layer remains above a second section of the second layer; and growing the second layer within the recess, and planarizing top surfaces of the first layer and the second layer, thereby forming the substrate comprising the first and second layers.

Example 32. The method of example 31, wherein forming the first layer above the second layer comprises: forming a layer of insulator material above the second layer; and forming the first layer above the layer of insulator material.

Example 33. The method of example 32, wherein selectively removing the first layer comprises: selectively removing the first layer and the layer of insulator material from above the first section of the second layer, such that the first layer and the layer of insulator material remain above the second section of the second layer.

Example 34. The method of any one of examples 31-32, wherein forming the substrate further comprises: subsequent to selectively removing the first layer, forming a spacer on a sidewall wall of the first layer, wherein after growing the second layer within the recess, the spacer is laterally between and separates (i) the first layer and (ii) the portion of the second layer that is grown within the recess.

Example 35. The method of any one of examples 31-34, wherein: the first fin is above the second section of the second layer; and the second fin is above the first section of the second layer.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An integrated circuit structure comprising:
a substrate;
a first device above a first section of the substrate, the first device comprising
a first source region and a first drain region, and
a first body extending laterally between the first source and first drain regions, the first body comprising silicon with crystalline orientation described by Miller index of (100); and
a second device above a second section of the substrate, the second device comprising
a second source region and a second drain region, and
a second body extending laterally between the second source and second drain regions, the second body comprising silicon with crystalline orientation described by Miller index of (110).

2. The integrated circuit structure of claim 1, wherein:
the first section of the substrate, above which the first device is formed, comprises silicon with crystalline orientation described by Miller index of (100).

3. The integrated circuit structure of claim 1, wherein:
a top portion of the second section of the substrate, above which the second device is formed, comprises silicon with crystalline orientation described by Miller index of (110); and
a bottom portion of the second section of the substrate, above which the second device is formed, comprises silicon with crystalline orientation described by Miller index of (100).

4. The integrated circuit structure of claim 3, further comprising:
a layer comprising insulator material between the top and bottom portions of the second section of the substrate.

5. The integrated circuit structure of claim 3, further comprising:
a layer comprising oxygen between the top and bottom portions of the second section of the substrate.

6. The integrated circuit structure of claim 1, wherein the first device is a n-channel metal-oxide-semiconductor (NMOS) device, and the second device is a p-channel metal-oxide-semiconductor (PMOS) device.

7. The integrated circuit structure of claim 1, further comprising:
a first gate structure at least in part wrapped around the first body, the first gate structure including (i) a first gate electrode and (ii) first gate dielectric between the first body and the first gate electrode; and
a second gate structure at least in part wrapped around the second body, the second gate structure including (i) a second gate electrode and (ii) second gate dielectric between the second body and the second gate electrode.

8. The integrated circuit structure of claim 7, wherein:
the first gate electrode and the second gate electrode form a continuous gate electrode structure.

9. The integrated circuit structure of claim 7, further comprising:
a first spacer between the first gate electrode and the first source region, and a second spacer between the first gate electrode and the first drain region,
wherein the first spacer is above and below a first tip region of the first body, and wherein the second spacer is above and below a second tip region of the first body.

10. The integrated circuit of claim 1, wherein the first device comprises one or more additional bodies extending laterally between the first source and first drain regions, the one or more additional bodies comprising silicon with crystalline orientation described by Miller index of (100).

11. The integrated circuit of claim 10, wherein the first body and the one or more additional bodies are included in a vertical stack including two or more nanowires, nanoribbons, or nanosheets.

12. The integrated circuit of claim 1, wherein the second device comprises one or more additional bodies extending laterally between the second source and second drain regions, the one or more additional bodies comprising silicon with crystalline orientation described by Miller index of (110).

13. An integrated circuit structure comprising:
a first source region and a first drain region;
a first body comprising first semiconductor material and extending laterally between the first source and first drain regions;
a second source region and a second drain region; and
a second body comprising second semiconductor material and extending laterally between the second source and second drain regions,
wherein a first crystalline orientation of the first semiconductor material is different from a second crystalline orientation of the second semiconductor material.

14. The integrated circuit structure of claim 13, wherein:
the first source region, the first drain region, and the first body form a n-channel metal-oxide-semiconductor (NMOS) device, and the first crystalline orientation is described by a Miller index of (100); and
the second source region, the second drain region, and the second body form a p-channel metal-oxide-semiconductor (PMOS) device, and the second crystalline orientation is described by a Miller index of (110).

15. The integrated circuit structure of claim 13, further comprising:
a substrate having (i) a first section, the first body above the first section, and (ii) a second section, the second body above the second section,
wherein the first section of the substrate comprises semiconductor material having the first crystalline orientation.

16. The integrated circuit structure of claim 15, wherein:
a top portion of the second section of the substrate comprises semiconductor material having the second crystalline orientation; and
a bottom portion of the second section of the substrate comprises semiconductor material having the first crystalline orientation.

17. The integrated circuit structure of claim 16, further comprising:
a layer comprising insulator material between the top and bottom portions of the second section of the substrate.

18. A method of forming an integrated circuit structure, comprising:
forming a stack of alternating layers of sacrificial material and channel material above a substrate, wherein each layer of channel material in the stack comprises (i) a first section having a first semiconductor material with a first crystalline orientation, and (ii) a second section having a second semiconductor material with a second crystalline orientation;
selectively etching the stack to define at least (i) a first fin having alternating layers of the first semiconductor material with the first crystalline orientation and the sacrificial material, and (ii) a second fin having alternating layers of the second semiconductor material with the second crystalline orientation and the sacrificial material;
forming (i) a first source region and a first drain region, such that the first fin is laterally between the first source region and the first drain region, and (ii) a second source region and a second drain region, such that the second fin is laterally between the second source region and the second drain region; and
removing the sacrificial material from the first and second fins, such that (i) the layers of the first semiconductor material with the first crystalline orientation of the first fin form a first plurality of bodies laterally between the first source region and the first drain region, and (ii) the layers of the second semiconductor material with the second crystalline orientation of the second fin form a second plurality of bodies laterally between the second source region and the second drain region.

19. The method of claim 18, wherein:
the first source region, the first drain region, and the first plurality of bodies laterally between the first source region and the first drain region form a p-channel metal-oxide-semiconductor (PMOS) device, and the first crystalline orientation is described by a Miller index of (110); and
the second source region, the second drain region, and the second plurality of bodies laterally between the second source region and the second drain region form a n-channel metal-oxide-semiconductor (NMOS) device, and the second crystalline orientation is described by a Miller index of (100).

20. The method of claim 18, further comprising forming the substrate, wherein forming the substrate comprises:
forming a first layer of the first semiconductor material with the first crystalline orientation above a second layer of the second semiconductor material with the second crystalline orientation;
selectively removing the first layer from above a first section of the second layer, to generate a recess over the first section of the second layer, such that the first layer remains above a second section of the second layer; and
growing the second layer within the recess, and planarizing top surfaces of the first layer and the second layer, thereby forming the substrate comprising the first and second layers.
